(19) United States
(12) Patent Application Publication
(10) Pub. No.: US 2007/0187696 A1
(43) Pub. Date: Aug. 16, 2007

(54) Semiconductor light emitting device

(76) Inventors: Shigeya Naritsuka, Aichi (JP); Takahiro Maruyama, Aichi (JP); Tatsuya Moriwake, Hyogo (JP)

Correspondence Address: MCDERMOTT WILL & EMERY LLP, 600 13TH STREET, N.W., WASHINGTON, DC, 20005-3096, US

(21) Appl. No.: 10/594,742

(22) PCT Filed: Mar. 24, 2005
(86) PCT No.: PCT/JP05/05379

§ 371 Date: Sep. 28, 2006

(30) Foreign Application Priority Data
Mar. 29, 2004 (JP) 2004-096321

(51) Int. Cl. H01L 33/00

(52) U.S. Cl. 257/79

(57) ABSTRACT

A semiconductor light emitting device including a transparent compound semiconductor substrate whose lattice constant is inconsistent with the compound semiconductor emitting the light and exhibiting high light output is obtained. A semiconductor light emitting device includes a GaP substrate, an active layer located above GaP substrate and including an n-type AlInGaP layer and a p-type AlInGaP layer, and an ELO layer located between GaP substrate and active layer and formed by epitaxial lateral growth.

### TECHNICAL FIELD

The present invention relates to a semiconductor light emitting device, and more particularly, to a semiconductor light emitting device in which light output is not decreased by absorption at a substrate and the like.

### BACKGROUND ART

Since a GaP semiconductor substrate is transparent in a visible to infrared light zone, it often tends to be used in many light emitting devices in visible to infrared light regions. Conventionally, the GaP substrate was used as shown in the following (a1) and (a2).

(a1) There is a difference of a little less than 4% between the lattice constant of a compound semiconductor such as GaAs and AlGaAs emitting light in visible to infrared light zone by direct transition and that of GaP. Thus, a fine epitaxial film of the compound semiconductor for light emission cannot be formed on the GaP substrate.

On the other hand, the lattice constant of GaAs which is common as the compound semiconductor generally corresponds to that of the above-described compound semiconductor for light emission. GaAs, however, has a high absorption rate of the above-described wavelength region, and thus, when used as the substrate, the absorption of light cannot be ignored because of its thickness.

Thus in fabricating a light emitting element, a method was proposed for attaching an epitaxial layer including the active layer on the GaP substrate after causing the epitaxial growth of the above-described AlGaAs film and the like to form an active layer and removing a part of the GaAs substrate (see Japanese Patent Laying-Open No. 6-302857 (patent document 1). According to this method, the eptaxial film including the active layer of superior crystallinity and the transparent GaP substrate are combined to form a LED having high output.

(a2) A lattice strain relaxation layer is provided on the GaP substrate, since a favorable epitaxial layer cannot be obtained if a compound semiconductor layer such as AlGaInP is directly formed on the GaP substrate. The lattice strain relaxation layer adjusts the composition of InGaP so that its lattice constant is between that of GaP and AlGaInP to approximate AlGanInP layer gradually. Thus, InGaP of a plurality of layers with different composition placed as the lattice strain relaxation layer is used (see Japanese Patent Laying-Open No. 2001-291895 (patent document 2). By arranging such a lattice strain relaxation layer, a transparent GaP susbstrate can be used from the beginning of the fabrication to obtain a light emitting element having high efficiency.

Patent Document 1: Japanese Patent Laying-Open No. 6-302857

Patent Document 2: Japanese Patent Laying-Open No. 2001-291895

### DISCLOSURE OF THE INVENTION

### Problems to be Solved by the Invention

In the above-described (a1) method, however, many steps are required to remove an originally fabricated substrate and put the part of the epitaxial layer on the GaP substrate, which is a great obstacle to the reduction of fabrication costs. Also, in the above-described (a2) method, since InGaP of a plurality of layers approaching the lattice constant of AlGaInP is gradually placed, many steps are required again, which prevents the reduction of the cost.

### Means for Solving the Problems

An object of the invention is to provide a semiconductor light emitting device including a compound semiconductor substrate that is transparent in the light of a predetermined wavelength band and whose lattice constant is inconsistent with the compound semiconductor emitting the light of the predetermined wavelength band while high light output can be ensured.

The semiconductor light emitting device of the invention includes a GaP substrate, an active layer including an n-type layer and a p-type layer of the compound semiconductor located above the GaP substrate, and an ELO layer located between the GaP substrate and the active layer and formed by epitaxial lateral growth.

With this construction, the ELO layer is grown on the GaP substrate through liquid phase epitaxial growth (LPE: Liquid Phase Epitaxial) superior in mass productivity. The GaP substrate provides an advantage of obtaining precipitous growth interface since the GaP substrate has the same constituent element Ga as the Ga used as a solution in LPE and GaAs of the ELO layer and the like. In addition, the GaP substrate has a lower solubility to Ga than GaAs of ELO layer and the like, and thus elution (melt back) to Ga is less likely to occur, which makes it suitable as a substrate causing growth of the ELO layer. Therefore, the compound semiconductor layer with superior crystallinity can be easily formed while reducing the fabrication costs.

### BRIEF DESCRIPTION OF THE DRAWINGS

FIG. 1 is a diagram illustrating a semiconductor light emitting device in a first embodiment of the present invention.

FIG. 2 is a diagram illustrating a modification of the semiconductor light emitting device of the first embodiment of the present invention.

FIG. 3 is a diagram illustrating another modification of the semiconductor light emitting device of the first embodiment of the present invention.

FIG. 4 is a diagram illustrating still another modification of the semiconductor light emitting device of the first embodiment of the present invention.

FIG. 5 is a diagram illustrating a semiconductor light emitting device of a second embodiment of the present invention.

FIG. 6 is a diagram illustrating a window pattern in the fabrication method of a semiconductor light emitting device of a third embodiment of the present invention.

FIG. 7 is a diagram illustrating an initial stage of growth of the ELO layer.

FIG. 8 is a diagram illustrating the collection position of the semiconductor light emitting device of the third embodiment of the present invention.

FIG. 9 is a diagram illustrating a grown ELO layer.

FIG. 10 is a diagram illustrating the collection position of another semiconductor light emitting device of the third embodiment of the present invention.

FIG. 11 is a diagram illustrating a pattern of a window portion in Example 1 of the present invention.

FIG. 12 is a diagram illustrating a slide-boat in a slide-boat method used in Example 1.

FIG. 13 is a diagram illustrating the semiconductor light emitting device in Example 2 of the present invention.

FIG. 14 is a diagram illustrating a pattern of a scratched trench or the window portion in Example 8 of the present invention.

FIG. 15 is a diagram illustrating a pattern of the scratched trench or the window portion in Example 9 of the present invention.

FIG. 16 is a diagram illustrating another pattern of the scratched trench or the window portion in Example 10 of the present invention.

FIG. 17 is a diagram illustrating another pattern of the scratched trench or the window portion in Example 11 of the present invention.

FIG. 18 is a diagram illustrating the modifications of the Examples 8 to 11 of the present invention.

FIG. 19 is a diagram illustrating another modifications of Examples 8 to 11 of the present invention.

FIG. 20 is a diagram illustrating another pattern of the scratched trench or the window portion in Example 12 of the present invention.

### DESCRIPTION OF THE REFERENCE SIGNS

1 substrate, 2 growth supporting layer, 2a window portion of the growth supporting layer, 2b upper surface of the growth supporting layer, 3 ELO layer, 3a growth starting position, 3b lower surface of the growth supporting layer, 4 active layer, 5 clad layer, 10 semiconductor light emitting device, 11 scratched trench, 12 GaAs buffer layer, 13 clad layer, 15 dislocation, 17 electrode, 19 cutting line, 30 laser oscillation unit, 51 sliding board, 52 boat.

### BEST MODES FOR CARRYING OUT THE INVENTION

Embodiments of the present invention will be described using the drawings.

### FIRST EMBODIMENT

FIG. 1 is a diagram illustrating a semiconductor light emitting device in the first embodiment of the invention. This semiconductor light emitting device 10 has a growth supporting layer 2 constituted of SiO₂ arranged on a GaP substrate 1, and an ELO layer 3 is placed on growth supporting layer 2, embedding a window portion (opening) 2a. In ELO layer 3, the lateral epitaxial growth can be easily confirmed by observing the cross section thereof.

In the semiconductor light emitting device shown in FIG. 1, ELO layer 3 is formed of GaAs. There is no specific relation of crystal orientation between ELO layer 3 epitaxially grown laterally from window portion 3a and growth supporting layer 2, and growth supporting layer 2 only supports ELO layer dynamically. ELO layer grows laterally from window portion 3a while maintaining the epitaxiality.

A clad layer 13 constituted of an n-type AlInGaP is placed on ELO layer 3 constituted of GaAs. An active layer 4 including the n-type AlInGaP layer and a p-type AlInGaP layer is placed on clad layer 13, and the p-type AlInGaP clad layer 5 is provided on active layer 4.

According to the structure of semiconductor light emitting device 10 shown in FIG. 1, ELO layer 3 having superior crystallinity can be readily formed by a simple process without having to provide a lattice strain relaxation layer whose composition is gradually changed.

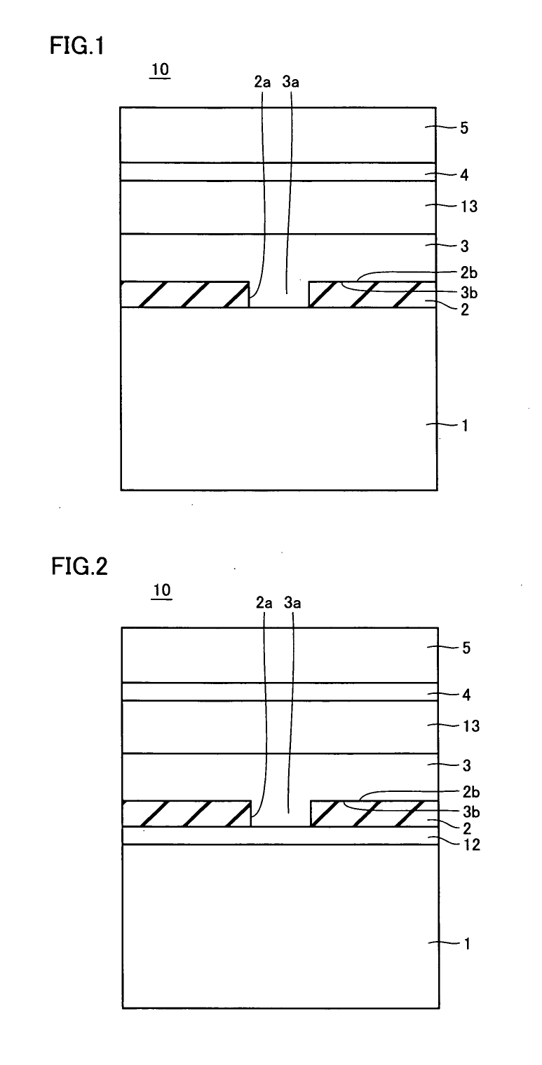

FIG. 2 is a diagram illustrating a modification of the semiconductor light emitting device of FIG. 1. In semiconductor light emitting device 10 shown in FIG. 2, a buffer layer 12 constituted of GaAs is placed between GaP substrate 1 and growth supporting layer 2. The formation of the buffer layer constituted of GaAs can provide the epitaxial layer with much better crystallinity.

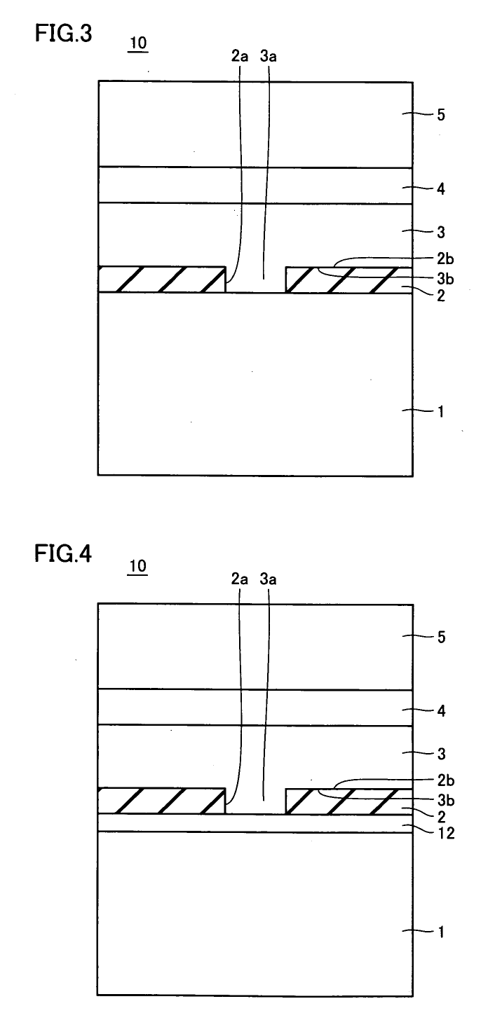

FIG. 3 is a diagram illustrating another modification of the semiconductor light emitting device of FIG. 1. In semiconductor light emitting device 10 shown in FIG. 3, AlGaAs is used for ELO layer 3, and this ELO layer constituted of AlGaAs also serves as the clad layer of the active layer. Further, an n-type AlGaAs layer and a p-type AlGaAs layer are included in active layer 4.

FIG. 4 has a structure in which ELO layer also serves as the clad layer in the semiconductor light emitting device shown in FIG. 2.

### SECOND EMBODIMENT

FIG. 5 is a diagram illustrating a semiconductor light emitting device of the second embodiment of the invention. This semiconductor light emitting device 10 has a scratched trench 11 provided on the surface of GaP substrate 1. ELO layer 3 constituted of GaAs is placed on the GaP substrate based on growth starting region 3a. There is no predetermined relation of crystal orientation (coherency) between a surface 1b of GaP substrate 1 and lower surface 3b of ELO layer 3. In growth starting region 3a, GaAs liquid phase is placed and epitaxially grown by LPE. During the epitaxial lateral growth, it is considered that epitaxial growth proceeds in substantially a free manner.

Clad layer 13 constituted of n-type AlInGaP is formed on ELO layer 3 constituted of GaAs, and active layer 4 including the n-type AlInGaP layer and the p-type AlInGaP layer is located on clad layer 13. A p-type clad layer 5 is formed on active layer 4.

In the above-described semiconductor light emitting device, since scratched trench 11 becomes the growth starting region without the necessity of providing the growth supporting layer with the window portion, a fabrication process can be simplified or the fabrication cost such as material cost can be reduced.

In the above-described first and second embodiments, the combination of the GaP substrate that is a transparent substrate and an AlInGaP layer that is the light emitting layer was described. The combination of the above-described GaP substrate and epitaxial light emitting layer, however, is not limited to the combination of AlInGaP layer and ELO layer. For example, ELO layer may be formed from any of an InGaAsP layer, InGaAs layer, GaAs layer, AlGaAs layer, AlInGaP layer, InGaP layer and GaAsP layer.

Further, although the example was described in which SiO₂ film was used for the growth supporting layer in the above-described embodiment, SiO₂ film can be replaced by the following materials having the similar effect.
(1) insulating material: metal oxide or nitride such as SiN, TiO₂, P₂O₃, Al₂O₃ and the like.
(2) conductive material: metal such as Ti, Fe, Pt, Ni and the like, and also as specific metal, refractory metal such as Co, W, Ta, Mo and the like (which is applicable to growth in high temperature)
(3) dielectric multilayered body: MgO₂/SiO₂ multilayer film, ZrO₂/SiO₂ multilayer film and the like.

### THIRD EMBODIMENT

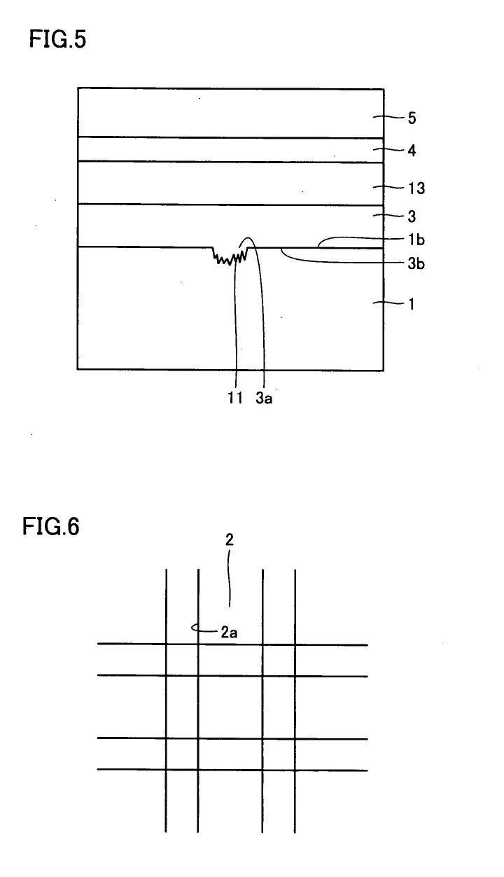

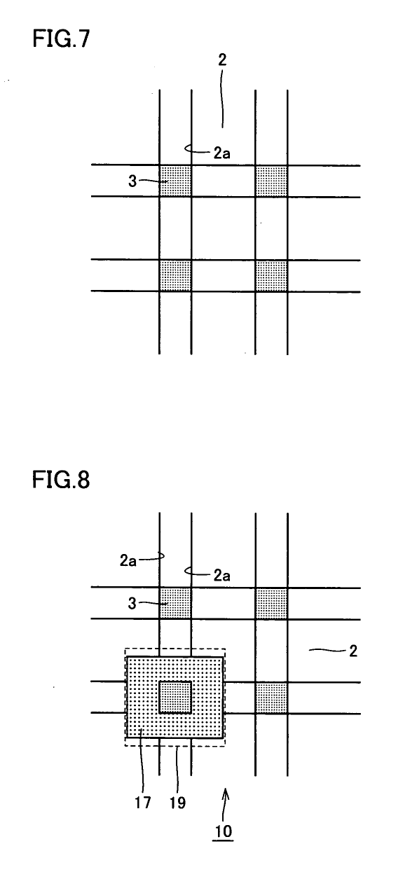

The third embodiment of the invention is characterized in that a part of the ELO film grown in the initial stage is employed as the light emitting portion by devising the pattern shape of the window portion. In this embodiment, a window portion 2a is provided as shown in FIG. 6. The epitaxial lateral growth using the pattern of the window portion shown in FIG. 6 causes growth at the entire area in the small square region surrounded by window portion 2a, as shown in FIG. 7. The area of ELO film 3 can be utilized as the main region of the light emitting device.

For example, as shown in FIG. 8, the active layer and the like are formed on ELO film, and an electrode 17 is formed such that it encompasses the region. By cutting at broken line 19 from the above-described substrate, a chip of the light emitting element can be obtained.

According to the aforementioned placement, the light emitting element with superior crystallinity can be easily obtained in the form suitable for mass production very easily.

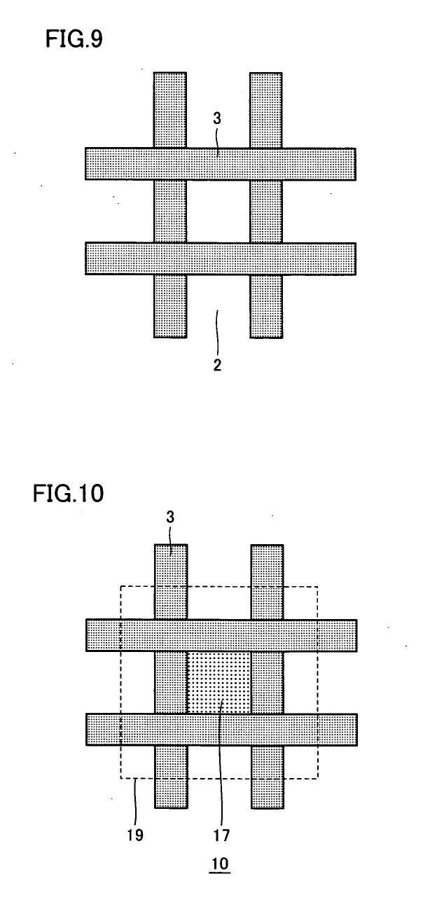

If the epitaxial lateral growth is further continued from the condition of FIG. 8, ELO film 3 expands from the small square region to grow to the shape shown in FIG. 9. In the condition in which ELO film 3 is grown, electrode 17 can be placed in the open space after the compound semiconductor film of the active layer is formed on ELO film.

Examples of the present invention will be described hereinafter.

### EXAMPLE 1

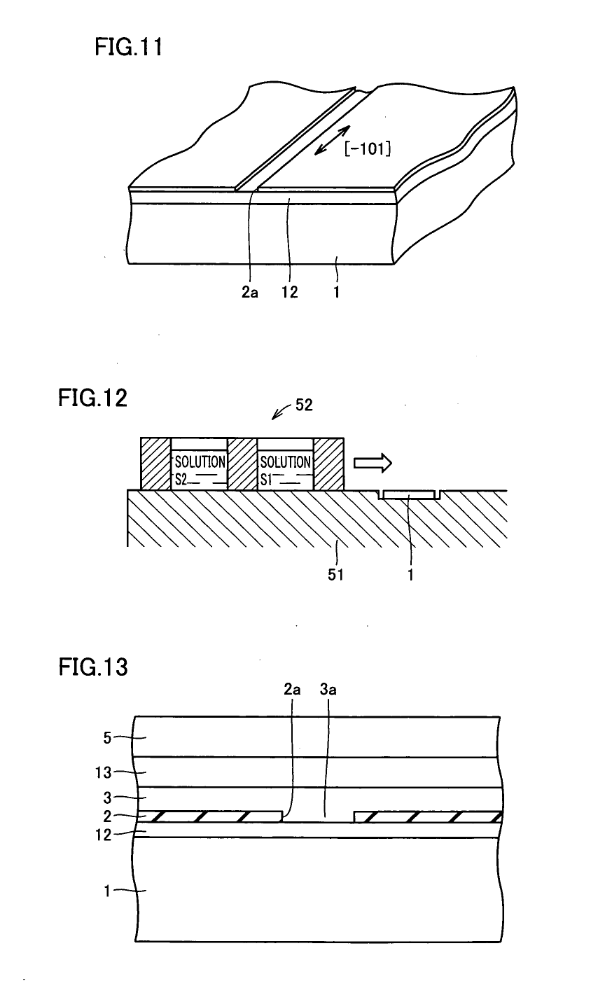

In Example 1 of the invention, the method of forming an ELO layer by LPE will be described. In the present embodiment, a GaP substrate was used as a semiconductor substrate. First, a GaAs buffer layer 12 was grown by means of the MBE method to the thickness of 0.1-1 μm on GaP substrate 1 whose main growth surface is the (111)_{B} surface. Growth supporting layer 3 of a SiO₂ film with the thickness of 0.1-0.5 μm was formed on GaAs buffer layer 12 by sputtering. Window portion 2a which is a portion in which the SiO₂ film was removed was formed on the SiO₂ film using the method of photolithography. In the present embodiment the window portion was formed in a linear shape of 20 μm of width parallel to the [−101] direction (FIG. 11).

ELO was conducted on GaP substrate 1 provided with growth supporting layer 2 having the above-described window portion using the LPE method under the following condition. In ELO growth, a growth device illustrated in FIG. 12 used in the slide boat method was used. As a solution reservoir, the following solution S1 for growth was used for processing.

Solution S1: GaAs was dissolved in Ga and Si was dissolved as an n-type impurity.

A boat 52 containing solution S1 is slid on a slide board 51 so that solution S1 is brought into contact with GaP substrate 1. During this contact, the furnace temperature is raised to 500° C. Gradual decrease of the temperature after the solution S1 was brought into contact with substrate 1 causes lateral growth from the window portion. Solution S1 is separated from the substrate at 490° C.

In order to observe the properties of the GaAsELO epitaxial film, the aforementioned epitaxial film was taken out after the substrate was cooled to room temperature. When the cross section of the epitaxial film was observed, a GaAsELO layer with 6 μm in thickness and 240 μm in width was recognized. When etching the surface with KOH etchant, dislocation was greatly observed at the window portion, while the dislocation was hardly observed in the epitaxially laterally grown portion.

### EXAMPLE 2

Example 2 of the present invention is characterized in that the ELO layer is formed using two types of solutions. In the present embodiment, the same process as the third embodiment was performed up to the stage of providing the growth supporting layer with the window portion. The solutions are as follows.

Solution S1: GaAs was dissolved in Ga and Si was dissolved as an n-type impurity.

Solution S2: GaAs was dissolved in Ga and Si was dissolved as an amnphoteric impurity.

The above-described solution is contained in boat 52 shown in FIG. 12. Boat 52 loaded with a solution reservoir is slid on slide board 51 to substrate 1 so that the solution can be brought into contact with substrate 1. Slide board 51, boat 52 and substrate 1 are placed in a temperatuire control furnace which can raise or decrease the temperature with accuracy.

First, when the solution S1 is brought into contact with GaP substrate 1, the furnace temperature is raised to 900° C. Gradual decrease of temperature after the solution S1 was brought into contact with GaP substrate 1 causes the lateral growth from the window portion. Solution S1 is separated from the GaP substrate after cooling it to 890° C. at 0.1° C./minute. Then solution S2 is brought into contact with GaP substrate. Subsequently, when it is cooled to 850° C. at 1° C./minute, an n-type GaAs layer 13 and a p-type GaAs 5 are grown at 890-880° C. and 880-850° C., respectively, by natural inversion of Si. Solution S2 is separated from GaP substrate at 850° C. Then, cooling is conducted down to room temperature. Subsequently, the epitaxial film including the active layer was taken out for observation of the ELO layer. As a result of the observation, it was confirmed that epitaxial growth of the epitaxial film with the width of 150 μm on one side from the window portion and with the width of 150 μm on the other side from the window portion, respectively (FIG. 13).

When the surface of the epitaxial film is observed after etched by KOH etchant, dislocation was greatly observed at the window portion while displacement was hardly observed on the laterally grown portion.

When the cross section of the epitaxial film was observed, the thickness of ELO layer, the n-type GaAs layer and the p-type GaAs layer was 8 μm, 10 μm, and 30 μm, respectively. Also, the above-described n-type GaAs layer 13 and p-type GaAs layer 5 can be regarded as the light emitting layer also serving as the clad layer.

When simplified electrodes were formed on the surface and backside and light was emitted by applying current, the light emitting element in the present embodiment which used the GaP substrate for the semiconductor substrate had light emission intensity of 1.5 times that of the light emitting element which used a GaAs substrate. This is because the GaP substrate is hardly susceptible to the absorption in the light emitting wavelength band of the above-described GaAs compared with the GaAs substrate, and thus is transparent.

### EXAMPLE 3

In Example 3 of the present invention, solution S1 used had GaAs and Al dissolved in Ga and Si dissolved as the n-type impurity. Using such a solution, an ELO layer was formed from the window portion of the GaP substrate. The ELO layer is transparent to emission wavelength from the p-n junction formed by GaAs. As a result, output could be further increased in comparison with Example 2.

### EXAMPLE 4

In Example 4 of the present invention, solution S2, solution S3 and solution S4 were used, and GaAs, Al and impurity were selected to adjust the band gap of the light emitting layer and the clad layer. By adjusting the composition of the epitaxial semiconductor layer, the band gap of the light emitting layer could be changed. As a result, it became possible to adjust the emission wavelength and output.

### EXAMPLE 5

In Example 5 of the present invention, p-n junction(emission region) is formed using an epitaxial growth method that is different from LPE, for example, MOCVD. Consequently, the epitaxial film which can most improve the crystallinity could be obtained.

### EXAMPLE 6

In Example 6 of the present invention, the growth of a GaAs buffer layer was omitted, and a SiO₂ film was formed directly on the GaP substrate. The window portion was formed in the SiO₂ film and an ELO film was grown by LPE. If the substrate temperature of the GaP substrate is not greater than 500° C. with respect to the dissolution of Ga in solution S1, there is almost no dissolution of GaP, and the ELO layer similar to the one obtained when a GaAs buffer was provided could be obtained. The reason why GaAs buffer layer can be omitted is that, at the temperature not greater than 500° C., solubility of GaP to Ga is considerably lower than that of GaAs to Ga. From the present example, we could confirm that the process of forming GaAs buffer layer could be omitted.

### EXAMPLE 7

In Example 7 of the present invention, a minute flaw (scratched trench) was provided on the GaP substrate using a diamond pen without forming an SiO₂ film of the growth supporting layer in the above-described Example 6, and the solution S1 of GaAs was brought into contact with the position including the scratched trench to form the ELO layer whose growth starting position is the scratched trench. When the ELO layer was grown by bringing the solution S1 into contact with the GaP substrate and reducing the cooling rate further to 0.05° C./minute, ELO growth occurred from the above-described scratched trench portion while epitaxial growth did not occur in the other region absent of a scratched trench.

This is because, due to the large difference that is approximately 4% in the lattice constant of GaP to GaAs, if the degree of supersaturation of GaAs is low, crystal growth is unlikely to occur, while in the minute concavo-convex region such as the scratching flaw, crystal growth originated in the region is more likely to occur.

### EXAMPLE 8

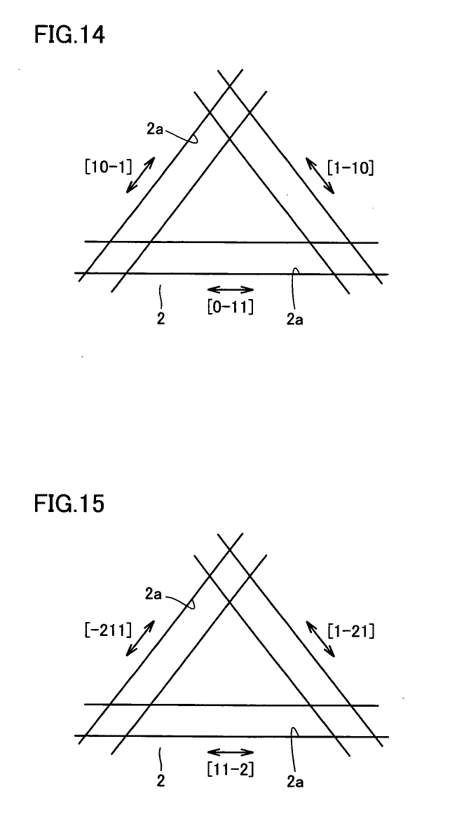

Example 8 of the present invention is characterized in that the main surface of the GaP substrate is made to be the (111)B side, and the longitudinal direction of the scratched trench or the window portion is made to be a particular crystal orientation. The scratched trench or the window portion was made to be an equilateral triangle and its aggregation with the direction s of the three sides parallel to [10-1], [1-10] and [0-11], respectively (see FIG. 14). Although window portion 2a formed in growth supporting layer 2 is shown in FIG. 14, scratched trench 11 (see FIG. 5), if used, may be formed in the region where window portion 2a was formed in FIG. 14 without having to form growth supporting layer 2. By using such a scratched trench or window portion, an ELO layer could be obtained selectively only inside and at the periphery of a triangle scratched trench or window portion. Since lateral growth is least likely to occur in this orientation, selectivity of growth is particularly high.

### EXAMPLE 9

Example 9 of the present invention is characterized in that the main surface of the GaP substrate is made to be (111)B side, and the longitudinal direction of the scratched trench or window portion is made to be a particular crystal orientation different from that of Example 8. The three sides in the longitudinal direction of the scratched trench or window portion were made to be an equilateral triangle and its aggregation parallel to [−211], [11-2], and [1-21], respectively (see FIG. 15), on which the ELO layer was grown by bringing the solution S1 into contact in a similar way to the above-described Examples 1 and 8. As a result, an ELO layer could be obtained selectively only inside and at the periphery of the equilateral triangle scratched trench or the window portion. Although window portion 2a formed in growth supporting layer 2 is shown in FIG. 15, scratched trench 11 (see FIG. 5), if used, may be formed in the region where window portion 2a was formed in FIG. 15 without having to form growth supporting layer 2.

### EXAMPLE 10

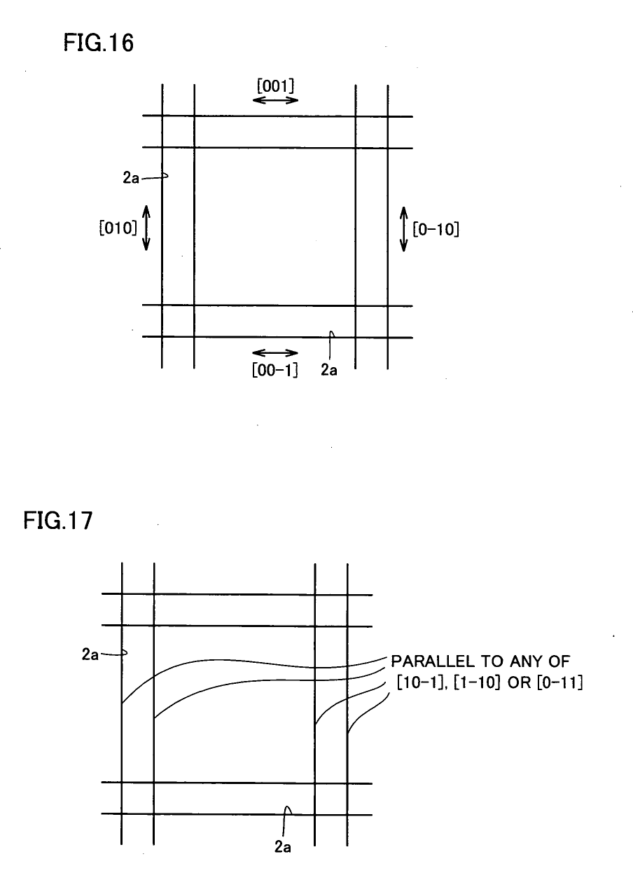

Example 10 of the present invention is characterized in that the main surface of the GaP substrate is made to be (100) side, and the longitudinal direction of the scratched trench or the window portion is made to be a particular crystal orientation different from the above-described Examples 8 and 9. In the present example, a quadrangle having parallel sides and its aggregation with the longitudinal direction of the scratched trench or window portion as in [001], [0-10], [00-1], and [010] respectively, (see FIG. 16) was employed, on which the ELO layer was formed by bringing the solution S1 into contact. As a result, an ELO layer could be obtained selectively only inside and at the periphery of a quadrangle scratched trench. Since in this orientation lateral growth is least likely to occur, especially selectivity of growth is high. Although window portion 2a formed in growth supporting layer 2 is shown in FIG. 16, scratched trench 11 (see FIG. 5), if used, may be formed in the region where window portion 2a was formed in FIG. 16 without having to form growth supporting layer 2.

### EXAMPLE 11

Example 11 of the present invention is characterized in that the main surface of the GaP substrate is made to be (100) side, and the longitudinal direction of the scratched trench or the window portion is made to be a particular crystal orientation. different from the above-described Examples 8-10. In the present example, a quadrangle and its aggregation was employed, in which the directions of four sides form 22.5° with respect to [001], [0-10], [00-1], and [010], respectively (see FIG. 17) in the longitudinal direction of the scratched trench or the window portion. Thereon, the ELO layer was formed by bringing the solution S1 into contact. As a result, an ELO layer could be obtained selectively only inside and the periphery of the scratched trench or the window portion arranged in quadrangle. Although window portion 2a formed in growth supporting layer 2 is shown in FIG. 17, scratched trench 11 (see FIG. 5), if used, may be formed in the region where window portion 2a was formed in FIG. 17 without having to form growth supporting layer 2.

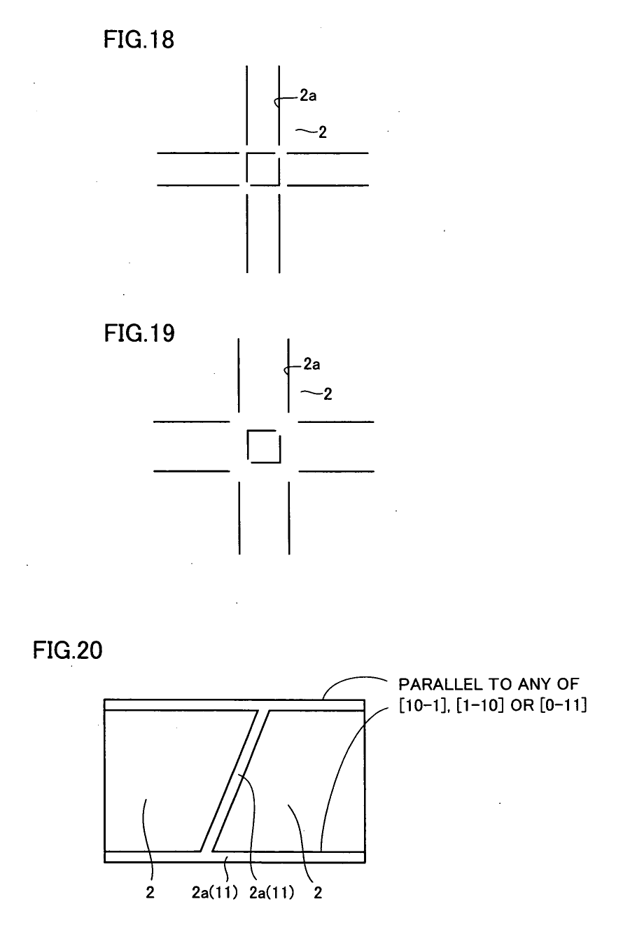

FIG. 18 and FIG. 19 are the diagrams illustrating the modifications of the arrangements of the scratched trench or the window portion shown in FIG. 6 and FIGS. 14-17. Although window portion 2a formed in growth supporting layer 2 is shown in FIG. 18 and FIG. 19, if scratched trench 11 (see FIG. 5) is used, scratched trench 11 may be formed in the region where window portion 2a was formed in FIG. 18 and FIG. 19 without having to form growth supporting layer 2. In these figures, the scratched trench or the window portion are formed by straight lines or broken lines having different intervals. This straight line or broken line is periodically formed so that a closed region having different size is epitaxially laterally grown. Similar effects to those shown in FIG. 6 and FIG. 14-FIG. 17 can be acquired by the scratched trench or the window portion.

### EXAMPLE 12

Example 12 of the present invention is characterized in that the main surface of the GaP substrate is made to be (111)B side, and the longitudinal direction of the scratched trench or the window portion is made to be a particular crystal orientation different from the above-described Examples 8-11. In the present example, as shown in FIG. 20, the GaP substrate is made to be a rectangle having two sides parallel to any of [10-1], [1-10] and [0-11], and the scratched trench or the window portion was formed at ends along the aforementioned two sides and on a straight line connecting them.

A container of solution S1 having an area larger than that of the GaP substrate was moved onto the GaP substrate to cause ELO growth in such a state. By such an ELO growth, the ELO layer could be readily obtained throughout the GaP substrate.

### EXAMPLE 13

Example 13 of the present invention is characterized in that the main surface of the GaP substrate is made to be (111)B side, and the longitudinal direction of the scratched trench or the window portion is made to be a particular crystal orientation different from the above-described Examples 8-12. In the present example, the GaP substrate is made to be a rectangle having two sides parallel to any of [−211], [11-2] and [1-21], and the scratched trench or the window portion was formed at ends along the aforementioned two sides and on a straight line connecting them.

A container of solution S1 having an area larger than that of the GaP substrate was moved onto the GaP substrate to cause ELO growth in such a state. By such an ELO growth, the ELO layer could be readily obtained throughout the GaP substrate.

### EXAMPLE 14

Example 14 of the present invention is characterized in that the main surface of the GaP substrate is made to be (100) side, and the longitudinal direction of the scratched trench or the window portion is made to be a particular crystal orientation different from the above-described Examples 8-13. In the present example, the GaP substrate is made to be a rectangle having two sides parallel to any of [021], [012], [0-21] and [0-12], and the scratched trench or the window portion was formed at ends along the aforementioned two sides and on a straight line connecting them.

A container of solution S1 having an area larger than that of GaP substrate is moved onto the GaP substrate to cause ELO growth in such a state. By such an ELO growth, the ELO layer could be readily obtained throughout the GaP substrate.

### EXAMPLE 15

Example 15 of the present invention is characterized in that the main surface of the GaP substrate is made to be (100) side, and the longitudinal direction of the scratched trench or the window portion is made to be a particular crystal orientation different from the above-described Examples 8-14. In the present example, the GaP substrate is made to be a rectangle having two sides parallel to any of [001], [0-10], [00-1] and [010], and the scratched trench or the window portion was formed at ends along the above-described two sides and on a straight line connecting them.

A container of solution S1 having an area larger than that of GaP substrate was moved onto the GaP substrate to cause ELO growth in such a state. By such an ELO growth, the ELO layer could be readily obtained throughout the GaP substrate.

Modifications of the invention will be described hereinafter including the above-described embodiments and examples of the present invention.

A growth supporting layer located abutting and under the above-described ELO layer is provided. The ELO layer fills the window portion opened in the growth supporting layer, and may grow laterally on and in contact with the growth supporting layer.

By thus providing the growth supporting layer, an epitaxial semiconductor film (ELO film) with superior crystallinity can be stably formed.

A buffer layer of the compound semiconductor is provided on the above-described GaP substrate, a growth supporting layer is located on and in contact with the buffer layer, and an ELO layer fills the window portion so that it comes into contact with the buffer layer, and it may grow on and in contact with the growth supporting layer.

With this placement, elution of the substrate does not occur even if the ELO layer is formed at a temperature not less than the predetermined temperature by LPE.

The above-described growth supporting layer is located in contact with the GaP substrate, the ELO layer fills the window portion so that it comes into contact with the GaP substrate and it may grow on and in contact with the growth supporting layer.

With this placement, the buffer layer can be omitted and the ELO layer can be formed at the temperature range not greater than the predetermined temperature.

In addition, the above-described GaP substrate is provided with the scratched trench, the ELO layer fills the scratched trench provided in the GaP substrate and it may grow laterally abutting on the GaP substrate.

With this placement, since the scratched trench functions as the growth starting position in LPE method similar to the above-described window portion, it is possible to form an ELO film, omitting the processes of forming the growth supporting layer and patterning the window portion.

In addition, the above-described window portion or scratched trench is placed linearly and/or in a broken line on both sides in such a way that it sandwiches the predetermined space so that the pattern may be periodic when viewed in plane.

With this placement, the light emitting element chip is formed in a periodic arrangement and the semiconductor light emitting device can be mass-produced efficiently.

Further, in a plan view, the ELO layer is located so that it is encompassed by the window portion, and electrodes may be arranged so that they surround the ELO layer encompassed by the window portion.

With this placement, it is possible to arrange the electrodes efficiently without blocking the emission surface of the light emitting element.

Further, in a plan view, the ELO layer is located so that it is encompassed by the window portion and it surrounds the partial region of the growth supporting layer, and that the electrode can be located on the partial region surrounded by the ELO layer.

With this placement, the electrode can be arranged efficiently without blocking the emission surface.

Further, the ELO layer may be formed from any of an InGaAsP layer, InGaAs layer, GaAs layer, AlGaAs layer, AlInGaP layer, InGaP layer and GaAsP layer.

According to the above-described arrangement, the combination can be selected matching the application, economical efficiency and the like.

In addition, the above-described ELO layer may be formed using the liquid phase epitaxial growth method, which makes it possible to form the ELO layer with superior crystallinity efficiently.

Further, the above-described growth supporting layer may be any of an insulator, conductor, and dielectric multilayered body.

With this placement, it is possible to select the material of the growth supporting layer adapted to the combination of the ELO film and the substrate.

Although the embodiment of the present invention has been described above, the same disclosed above is by way of illustration and example only and the scope of the present invention is not limited to these embodiments of the present invention. The scope of the present invention is illustrated by the terms of the claims, and is intended to include any modifications within the scope and meaning equivalent to the scope of the claims.

### INDUSTRIAL APPLICABILITY

With the semiconductor light emitting device of the invention, the epitaxial film including the active layer can be easily formed with fewer processes on a transparent substrate in which the matching of the lattice constant exceeds the predetermined range. Thus it is expected to be used in a wide range as light sources of a portable telephone and a variety of display devices.

1. A semiconductor light emitting device, comprising:
a GaP substrate;
an active layer located above said GaP substrate and including an n-type layer and a p-type layer of a compound semiconductor;
an ELO layer located between said GaP substrate and said active layer and formed by epitaxial lateral growth.

2. The semiconductor light emitting device according to claim 1, comprising a growth supporting layer located under and in contact with said ELO layer, wherein said ELO layer fills a window portion formed in said growth supporting layer, and grows laterally abutting on the growth supporting layer.

3. The semiconductor light emitting device according to claim 2, comprising a buffer layer of the compound semiconductor on said GaP substrate, wherein said growth supporting layer is located on and in contact with the buffer layer, and said ELO layer fills said window portion so that said ELO layer is in contact with the buffer layer and grows abutting on said growth supporting layer.

4. The semiconductor light emitting device according to claim 2, wherein said growth supporting layer is located in contact with said GaP substrate, said ELO layer fills said window portion so that said ELO layer is in contact with the substrate and grows abutting on said growth supporting layer.

5. The semiconductor light emitting device according to claim 2, wherein said window portion is arranged linearly and/or in a broken line on both sides so as to sandwich a predetermined space, and has a pattern that is periodic in a plan view.

6. The semiconductor light emitting device according to claim 2, wherein in a plan view, said ELO layer is located to be encompassed by said window portion, and an electrode is arranged to surround said ELO layer encompassed by the window portion.

7. The semiconductor light emitting device according to claim 2, wherein in a plan view, said ELO layer is encompassed by said window portion and located so as to surround a partial region of said growth supporting layer, and an electrode is located on the partial region surrounded by the ELO layer.

8. The semiconductor light emitting device according to claim 2, wherein said growth supporting layer is any of an insulator, conductor and dielectric multilayered body.

9. The semiconductor light emitting device according to claim 1, wherein said GaP substrate is provided with a scratched trench, said ELO layer fills the scratched trench provided in said GaP substrate, and grows laterally abutting on the GaP substrate.

10. The semiconductor light emitting device according to claim 9, wherein said scratched trench is arranged linearly and/or in a broken line on both sides so as to sandwich the predetermined space and has a pattern that is periodic in a plan view.

11. The semiconductor light emitting device according to claim 1, wherein said ELO layer is any of an InGaAsP layer, InGaAs layer, GaAs layer, AlGaAs layer, AlInGaP layer, InGaP layer, and GaAsP layer.

12. The semiconductor light emitting device according to claim 1, wherein said ELO layer is formed through a liquid phase epitaxial growth.
